(19) United States
(12) Patent Application Publication
(10) Pub. No.: US 2015/0362096 A1
(43) Pub. Date: Dec. 17, 2015

(54) CABLE SECURING APPARATUS AND METHOD OF SECURING A CABLE

(71) Applicant: International Business Machines Corporation, Armonk, NY (US)

(72) Inventors: Jean-Philippe Durney, Grabels (FR); Guillaume Hoareau, Montpellier (FR); Cedrine Madera, Castelnau-le-lez (FR); Romain Pochard, Montpellier (FR)

(21) Appl. No.: 14/703,157

(22) Filed: May 4, 2015

(30) Foreign Application Priority Data
Jun. 11, 2014 (GB) 1410361.8

(51) Int. Cl. F16L 3/227; H05K 7/12; H01R 13/639; F16G 11/04

(52) U.S. Cl. CPC F16L 3/227; F16G 11/04; H05K 7/12; H01R 13/639

(57) ABSTRACT

Method and apparatus are provided for securing a cable. The apparatus includes: a substantially cone-shaped member having an elongate opening along the axis of the cone in which a cable is placeable in use; a holding member having at least one open-sided aperture in which the cone-shaped member is houseable in use; wherein the widest diameter of the cone-shaped member is greater than the diameter of the open-sided aperture of the holding member. The method of securing a cable may include: placing a cable in a substantially cone-shaped member having an elongate opening along the axis of the cone in which the cable is placeable; and inserting the cone-shaped member in a holding member having at least one open-sided aperture.

### FIELD OF INVENTION

This invention relates to the field of securing cables. In particular, the invention relates to securing cables to prevent improper unplugging.

### BACKGROUND

Data centers represent some of the most demanding performance technology in the communications infrastructure market. Choosing the right cabling and cable management system is one of the most important aspects of data center design. Reliability, in combination with extreme density, should guide the choice of products.

In the market of virtualization, physical connections are shared by more and more virtual machines and workloads. In this context cable security and reliability are keys to guarantee business continuity. Moreover, the density growth of servers in datacenters increases the number of cables per square meter and so increases the risk of improper unplugging of cables due to the cables' weight and maintenance in the datacenters.

Cabling best practices are not enough to prevent improper unplugging. There is a need to protect plugged cables and electronic or electrical elements' connectors in case of improper unplugging due to overweight of cable in connectors or violent wresting of cables.

With time and the increase of the cable density, the risk of improper unplugging of cables increases.

Whatever the root causes, the outcomes are often the same, in that electronic or electrical equipment is unplugged and, in the worse case, their connectors are broken. In addition, this leads to the services of the electronic equipment being are disrupted.

This problem arises in all forms of infrastructure in which there is dense cabling including datacenters, telecommunication centers, electrical equipment hubs, as well as moving vehicles such as aircraft, boats, rockets, etc.

Existing solutions to this problem are focused on the resilience and robustness of each cable itself or imply usage of hardened connectors. Main drawbacks of these solutions are extra cost of each cable because of their design, and an important loss of agility manipulating this kind of cables because they are less flexible.

Therefore, there is a need in the art to address the aforementioned problems.

### BRIEF SUMMARY OF THE INVENTION

According to a first aspect of the present invention there is provided a cable securing apparatus, comprising: a substantially cone-shaped member having an elongate opening along the axis of the cone in which a cable is placeable in use; a holding member having at least one open-sided aperture in which the cone-shaped member is houseable in use; wherein the widest diameter of the cone-shaped member is greater than the diameter of the open-sided aperture of the holding member.

The substantially cone-shaped member may have a cut-away segment extending radially from the elongate opening, wherein the cut-away section extends radially between approximately 10 degrees and approximately 135 degrees.

Preferably, the substantially cone-shaped member may be in the form of a truncated cylindrical cone.

The elongate opening along the axis of the cone may have a diameter concentric with the axis of the cone and substantially similar to the diameter of a cable. Different diameters of cables may be accommodated by providing various substantially cone-shaped members with differing diameters of elongate opening.

The substantially cone-shaped member is formed of a flexible material in order to accommodate a cable placeable in the cone-shaped member in use.

The holding member may be formed of a solid material and fixed in position providing a secure positioning of the substantially cone-shaped member in use. The holding member may have multiple open-sided apertures for housing multiple cone-shaped members each having a cable extending therethrough in use.

The at least one open-sided aperture of the holding member may be in the form of a tapered cylindrical aperture with a taper generally corresponding in angle with the angle of the substantially cone-shaped member.

The holding member may have a closing plate for closing the at least one open-sided aperture once at least one substantially cone-shaped member is placed in the at least one open-sided aperture.

According to a second aspect of the present invention there is provided a method of securing a cable, comprising: placing a cable in a substantially cone-shaped member having an elongate opening along the axis of the cone in which the cable is placeable; inserting the cone-shaped member in a holding member having at least one open-sided aperture; wherein the widest diameter of the cone-shaped member is greater than the diameter of the open-sided aperture of the holding member thereby preventing the cone-shaped member being pulled through the open-sided aperture of the holding member in a given direction.

The substantially cone-shaped member may be sufficiently flexible to clamp around the cable if pulled in the given direction. The given direction may be away from a connection of the cable to equipment.

Placing the cable in the substantially cone-shaped member may place the cable through a cut-away segment of the substantially cone-shaped member extending radially from the elongate opening.

Closing the at least one open-sided aperture may be carried out by attaching a closing plate across the open-sided apertures of the holding member.

According to a third aspect of the present invention there is provided a method substantially as described with reference to the figures.

According to a fourth aspect of the present invention there is provided a system substantially as described with reference to the figures.

The described aspects of the invention provide the advantage of preventing improper unplugging of electronic or electrical equipment whilst using standard cabling.

### BRIEF DESCRIPTION OF THE DRAWINGS

The subject matter regarded as the invention is particularly pointed out and distinctly claimed in the concluding portion of the specification. The invention, both as to organization and method of operation, together with objects, features, and advantages thereof, may best be understood by reference to the following detailed description when read with the accompanying drawings.

Preferred embodiments of the present invention will now be described, by way of example only, with reference to the following drawings in which:

FIG. 1 is an exploded perspective view of an example embodiment of an apparatus in accordance with the present invention;

FIGS. 2A and 2B are perspective views of alternative embodiments of the cone-shaped member of an apparatus in accordance with the present invention;

FIG. 2C is a perspective view of an alternative embodiment of the holding member of an apparatus in accordance with the present invention;

FIGS. 3A to 3C are perspective views of the component of the apparatus of FIG. 1 in three stages of a method of securing a cable in accordance with the present invention; and

FIG. 4 is a flow diagram of an example embodiment of a method in accordance with the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numbers may be repeated among the figures to indicate corresponding or analogous features.

### DETAILED DESCRIPTION OF PREFERRED EMBODIMENTS

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

Method and apparatus are provided for protecting each individual cable from improper unplugging, whatever the cause of the unplugging may be. The term cable is used herein to mean any form of elongate flexible electrical conductor including but not limited to wires, leads, flexes, etc.

The described apparatus is positioned upstream on a cable from connectors to electronic or electrical equipment. The apparatus will resist any force on the cable instead of the connectors themselves. The apparatus includes a smarter collar circling each cable fitting in an armed and resilient structure. No excessive pressure will be transmitted to the connectors or the equipment itself.

This apparatus may be provided in an infrastructure in which multiple cables are present. For example, the infrastructure may be a datacenter in which multiple electronic components are housed each having connecting cables. In another example, the infrastructure may be embedded in a moving vehicle such as aircraft, boat, rocket, etc.

The apparatus provides a cone-shaped member which encloses a cable at a position along the cable. The cone-shaped member is sized to comply with different cable diameters. The apparatus also provides a holding member in the form of a fixed comb member for securing one or more cables by securing the cone-shaped members in holes in the comb member.

The described apparatus is a hardening system to be installed at a step or position before connectors to equipment. The apparatus includes a cone-shaped member which acts as a collar to reduce tracking pressure at the surface of a cable. The cone-shaped member once applied on a cable is parked in a robust comb member. Any force applied to the cable in a direction away from the equipment will force the cone-shaped member into the comb member and thereby tighten the grip of the cone-shaped member around the cable preventing any slip or movement of the cable within the cone-shaped member.

The apparatus helps to:
Protect equipment plugs from a violent pull;
Protect cable connectors from violent pull;
Protect cable connectors from bending or folding;
Spread equally the weight pressure on the cable at the apparatus level;
Secure by design at the cable level and not at a bulk of cable level.

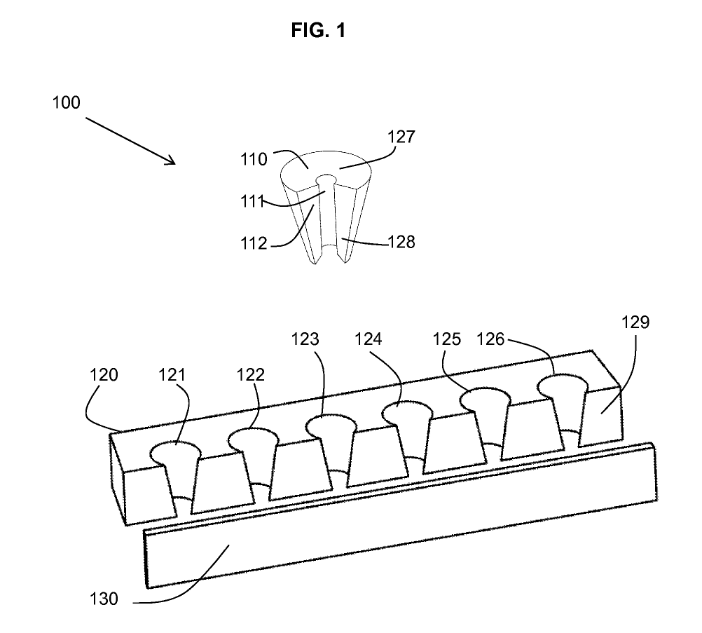

Referring to FIG. 1, an exploded view shows example embodiments of the components of the described cable securing apparatus. The cable securing apparatus 100 is formed of three parts: a cone-shaped member 110, a holding member 120 (also referred to as a comb member), and an, optional, closing plate 130.

The cone-shaped member 110 may be formed of a flexible plastics or rubber material also being resilient. In this example embodiment, the cone-shaped member 110 is in the form of a truncated cylindrical cone having an elongate aperture 111 along the axis of the cone in which a cable may be placed.

In order to allow a cable to be placed in the elongate aperture 111, the cone-shaped member 110 has a cut-away portion 112. The cut-away portion 112 may extend radially at an angle of between approximately 10 degrees and approximately 135 degrees. In the illustrated embodiment, the cut-away portion 112 has an angle of approximately 90 degrees. The cut-away portion 112 must enable a cable to be located in the elongate aperture 111 whilst ensuring that the elongate aperture 111 surrounds a cable sufficiently to hold the cable in place and prevent the cable from slipping out of the elongate aperture 111.

The cone-shaped member 110 may have an first end 127 with a wider diameter tapering to a second end 128 having a smaller truncated diameter of the cone.

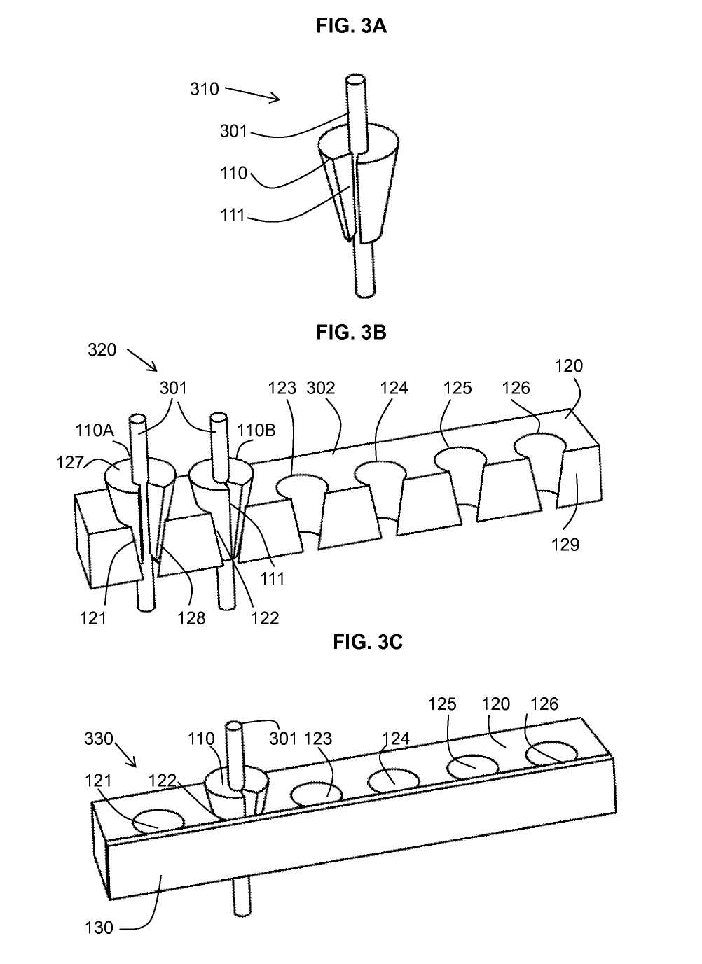

In use, the flexible, resilient cone-shaped member 110 may be flexed to allow a cable to be inserted into the elongate aperture 111. In use, as explained further in relation to FIGS. 3A to 3C, the cone-shaped member 110 may be squeezed into an aperture which will tighten the grip of the flexible cone-shaped member 110 around the cable.

The holding member 120 may be in the form of a comb shaped member with at least one aperture 121 and, possibly, a row of apertures 121 to 126 having open sides such that a cone-shaped member 110 attached around a cable may be inserted into an aperture 121-126.

The holding member 120 may be formed of a hard, rigid material, such as metal, and may be fixed in position, for example, in a rack, against a wall or other permanent fixture.

The holding member 120 may be in the shape of a rectangular prism with the apertures 121-126 being cylindrical or tapered cylindrical in shape. In the case of the apertures being of tapered cylindrical shape, the angle of tapering may correspond to the angle of the truncated cone of the cone-shaped member 110.

The open sides of the apertures 121-126 may be positioned along one wall 129 of the rectangular prism. The open sides of the apertures 121-126 may be just sufficiently wide to allow a cable on which the cone-shaped member 110 is positioned to pass.

The apertures 121-126 may each have a diameter of a size between the diameter of the first end 127 of the cone-shaped member 110 and the diameter of the second end 128 of the cone-shaped member 110. In use, the smaller diameter, second end 128 of the cone-shaped member 110 is positioned within an aperture 121-126.

A closing plate 130 may be provided for positioning along the wall 129 of the rectangular prism having the openings of the apertures 121-126. The closing plate 130 may be secured by various attachment means including clips, hinges, screw fastenings, sliding rails, etc.

In another embodiment, no closing plate may be needed if the open sides of the apertures 121-126 are only sufficiently wide to allow a cable to pass through so that, in use, the cone-shaped members 110 cannot move sideways out of the open sides of the apertures 121-126.

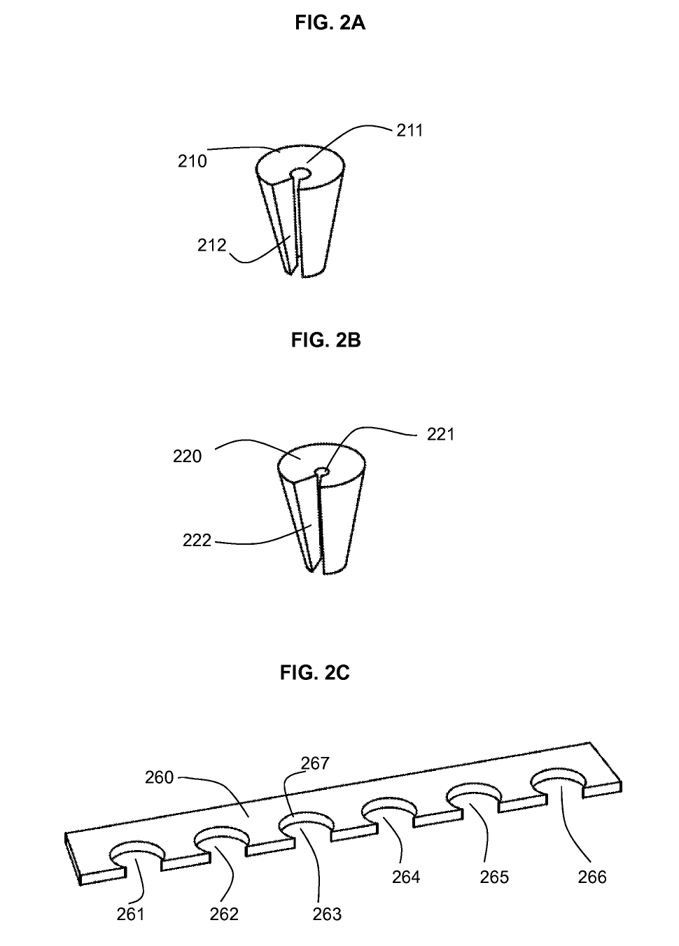

Referring to FIGS. 2A and 2B, additional example embodiments of the cone-shaped member 110 are shown. In FIG. 1, the cone-shaped member 110 is shown having a cut-away portion 112 of an angle of approximately 90 degrees.

In FIGS. 2A and 2B, the cone-shaped members 210, 220 have a cut-away portion 212, 222 of a smaller angle of approximately 45 degrees. These alternative embodiments of the cone-shaped member 210, 220, show other options in the possible range of the cut-away portions 212, 222.

In addition, FIG. 2B shows a smaller diameter of elongate aperture 221 suitable for a smaller cable or wire than the elongate aperture 211 of FIG. 2A.

Referring to FIG. 2C, an additional example embodiment of the holding member 260 is shown. In this embodiment, the holding member 260 may be a flat plate with less depth 267 of apertures 261-266. In this embodiment, a force on the cone-shaped member is applied by the circumference of the aperture 261-266 in the flat plate.

In use, a cone-shaped member 110, 210, 220 surrounding a cable, is inserted into an aperture 121-126 in the holding member 120. The cone-shaped member 110, 210, 220 may have its wider circumference on the side of the holding member 120 on which the electronic equipment is located. Any force applied to the cable in the direction of the smaller circumference will force the cone-shaped member 110, 210, 220 further into the aperture 121-126 thereby squeezing the flexible but resilient material of the cone-shaped member 110, 210, 220 to, in turn, squeeze around the cable holding it firmly in place and not allowing any force to be transmitted past the holding member 120. The cut-away portion 112, 212, 222 may be less than 135 degrees or the cable may be allowed to inadvertently come out of the elongate aperture 111.

Referring to FIGS. 3A, 3B, and 3C, a series of diagrams 310, 320, 330 show the method of use of the described cable securing apparatus.

In FIG. 3A, the cone-shaped member 110 is placed around a cable 301. The elongate aperture 111 of the cone-shaped member 110 may be provided in different diameters to suit different cables or wires. The cone-shaped member 110 is placed around a cable 301 by using the flexibility of the material of the cone-shaped member 110 to open the elongate aperture 111 slightly to allow the cable 301 to be inserted.

Referring to FIG. 3B, the cone-shaped member 110A, 110B is shown in place surrounding a cable 301 and inserted into one of the apertures 121, 122 of the holding member 120.

In a first position, the cone-shaped member 110A sits on a top side 302 of the holding member 120 with the first end 127 of the cone-shaped member 110 protruding from the aperture 122 whilst the second end 128 is within the aperture 121.

In a second position, in which a force has been applied to the cable 301, the cone-shaped member 110B sits deeper into the aperture 122 and the elongate aperture 111 surrounding the cable 301 has tightened.

FIG. 3C, shows the placement of the closing plate 130 over the apertures 121-126 of the holding member 120 thereby securing the one or more cone-shaped members 110 within the apertures 121-126 of the holding member 120.

The closing plate 130 may be hinged on the holding member 120 such that it only requires securing at one end of the holding member 120. In another embodiment, the closing plate 130 may be slid into place on runners on either side of the wall 129 having the open sides of the apertures 121 to 126.

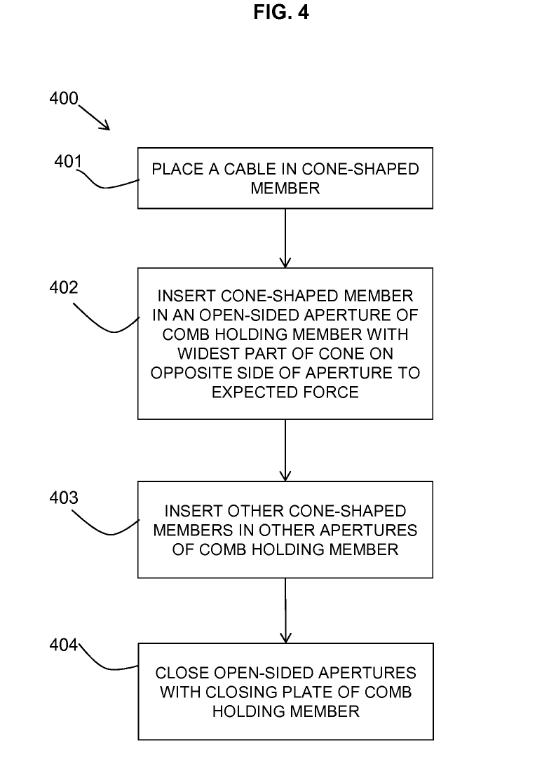

Referring to FIG. 4, a flow diagram 400 shows an example embodiment of a method of securing a cable using the described apparatus.

A cable is placed 401 in the cone-shaped member. The cone-shaped member may then be inserted 402 into an open-sided aperture of the comb holding member with the widest part of the cone on the opposite side of the aperture to the expected force.

Other cone-shaped members surrounding additional cables may be inserted 403 in other apertures of the comb holding member.

The open-sided apertures may be closed 404 with a closing plate of the comb holding member.

The described method and apparatus protect a cable or wire from an improper unplug by installing a hardening cone system made-up of soft material, like rubber or plastic just before connectors of electronic components. More specifically, the method and apparatus described fitting the cone-shaped member into a comb holding member, which acts as a collar to reduce tracking pressure at the surface of each individual cable or wire.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Improvements and modifications can be made to the foregoing without departing from the scope of the present invention.

1. A cable securing apparatus, comprising:
a substantially cone-shaped member having an elongate opening along an axis of the substantially cone-shaped member in which a cable is placeable in use;
a holding member having at least one open-sided aperture in which the cone-shaped member is houseable in use;
wherein a widest diameter of the cone-shaped member is greater than a diameter of the open-sided aperture of the holding member.

2. The apparatus as claimed in claim 1, wherein the substantially cone-shaped member has a cut-away segment extending radially from the elongate opening, wherein the cut-away section extends radially between approximately 10 degrees and approximately 135 degrees.

3. The apparatus as claimed in claim 1, wherein the substantially cone-shaped member is in the form of a truncated cylindrical cone.

4. The apparatus as claimed in claim 1, wherein the elongate opening along the axis of the substantially cone-shaped member has a diameter concentric with the axis of the substantially cone-shaped member and substantially similar to the diameter of a cable.

5. The apparatus as claimed in claim 1, wherein the substantially cone-shaped member is formed of a flexible material in order to accommodate a cable placeable in the cone-shaped member in use.

6. The apparatus as claimed in claim 1, wherein the holding member is formed of a solid material and fixed in position providing a secure positioning of the substantially cone-shaped member in use.

7. The apparatus as claimed claim 1, wherein the holding member has multiple open-sided apertures for housing multiple cone-shaped members each having a cable extending therethrough in use.

8. The apparatus as claimed in claim 1, wherein the at least one open-sided aperture of the holding member is in the form of a tapered cylindrical aperture with a taper generally corresponding in angle with the angle of the substantially cone-shaped member.

9. The apparatus as claimed in claim 1, wherein the holding member has a closing plate for closing the at least one open-sided aperture once at least one substantially cone-shaped member is placed in the at least one open-sided aperture.

10. A method of securing a cable, comprising:
placing a cable in a substantially cone-shaped member having an elongate opening along an axis of the substantially cone-shaped member in which the cable is placeable;
inserting the cone-shaped member in a holding member having at least one open-sided aperture;
wherein the widest diameter of the cone-shaped member is greater than the diameter of the open-sided aperture of the holding member thereby preventing the cone-shaped member being pulled through the open-sided aperture of the holding member in a given direction.

11. The method as claimed in claim 10, wherein the substantially cone-shaped member is sufficiently flexible to clamp around the cable if pulled in the given direction.

12. The method as claimed in claim 10, wherein placing the cable in the substantially cone-shaped member places the cable through a cut-away segment of the substantially cone-shaped member extending radially from the elongate opening.

13. The method as claimed in claim 10, including:
closing the at least one open-sided aperture by attaching a closing plate across the open-sided apertures of the holding member.

14. A cable securing apparatus, comprising:
a holding member adapted to be fixedly attached to a permanent fixture, wherein the holding member includes a plurality of open-sided apertures;
a plurality of substantially cone-shaped members, each having an elongate opening for receiving an electrical conductor along a longitudinal axis of the substantially cone-shaped member;
wherein each substantially cone-shaped member is mountable in a respective open-sided aperture of the holding member, and wherein a widest diameter of each cone-shaped member is greater than a diameter of a respective open-sided aperture.

15. The apparatus of claim 14, wherein the plurality of open-sided apertures of the holding member are arranged side by side within the holding member such that the holding member includes a surface with a plurality of side by side openings.

16. The apparatus of claim 14, wherein the electrical conductor comprises a data cable.

17. The apparatus of claim 14, wherein the electrical conductor comprises a power cable.

18. The apparatus of claim 14, wherein the plurality of substantially cone-shaped members comprise metal.

19. The apparatus of claim 14, wherein the plurality of substantially cone-shaped members comprise plastic.

20. The apparatus of claim 14, wherein the plurality of open-sided apertures of the holding member are substantially cone-shaped.
